(19) United States
(12) Patent Application Publication
(10) Pub. No.: US 2014/0038357 A1
(43) Pub. Date: Feb. 6, 2014

(54) SINGULATED IC STIFFENER AND DE-BOND PROCESS

(71) Applicants: Shawn X. ARNOLD, San Jose, CA (US); Matthew E. LAST, Santa Clara, CA (US); Shankar S. PENNATHUR, San Jose, CA (US); Tan ZHANG, San Jose, CA (US)

(72) Inventors: Shawn X. ARNOLD, San Jose, CA (US); Matthew E. LAST, Santa Clara, CA (US); Shankar S. PENNATHUR, San Jose, CA (US); Tan ZHANG, San Jose, CA (US)

(73) Assignee: Apple Inc., Cupertino, CA (US)

(21) Appl. No.: 13/604,617

(22) Filed: Sep. 5, 2012

Related U.S. Application Data
(60) Provisional application No. 61/680,245, filed on Aug. 6, 2012.

(51) Int. Cl. H01L 21/78

(52) U.S. Cl. 438/113; 438/464; 257/E21.599

(57) ABSTRACT

A method and apparatus is described for forming and using a stiffener for the production of thinned integrated circuits. In one embodiment, a handle can be bonded to an integrated circuit wafer before the wafer is thinned. Electrical couplings such as mounting balls can be attached to the wafer. Individual dice can be singulated from the wafer by dicing through the wafer and the handle, producing a wafer/handle assembly. The wafer/handle assembly can be mounted to a printed circuit board before the handle is de-bonded.

### CROSS-REFERENCE TO RELATED APPLICATION

This application claims priority to U.S. Provisional Patent Application No. 61/680,245, filed Aug. 6, 2012, and entitled “Singulated IC Stiffener and De-Bond Process”, which is incorporated herein by reference in its entirety and for all purposes.

### FIELD OF THE DESCRIBED EMBODIMENTS

The described embodiments relate generally to integrated circuits and more particularly to the use of stiffeners in the formation of thinned integrated circuit assemblies.

### BACKGROUND

Integrated circuits have long been used to reduce the space requirements for electrical designs, particularly digital electronic designs. Smaller space requirements usually translate to lower manufacturing and unit costs, decreased power consumption and ultimately smaller end user products for the consumer. Device form factors continue to shrink, pushing the normal limits of standard integrated circuit design.

One approach used to reduce volumetric space required to support an integrated circuit involves thinning the integrated circuit substrate. While the initial substrate can be quite thick, the substrate can be thinned to very thin amounts, often times approaching or less than 100 microns. One drawback to such thin substrates is that the substrates can be fragile, can warp or can crack or deform especially when the thinned integrated circuit is mounted or soldered to a supporting member, such as a printed circuit board.

Therefore, what is desired is a reliable way to produce thinned integrated circuit devices that are more robust and less subject to damage.

### SUMMARY OF THE DESCRIBED EMBODIMENTS

This paper describes various embodiments that relate to forming and mounting thinned integrated circuits.

In one embodiment, a method for forming a thinned integrated circuit can include the steps of bonding a handle to an integrated circuit substrate, thinning the integrated circuit substrate, separating individual dice from the thinned integrated substrate and de-bonding the handle from the dice after the dice is mounted to a supporting substrate.

In another embodiment, a method for forming a thinned circuit assembly can include the steps of bonding a first handle to a first side of an integrated circuit substrate, thinning the substrate, de-bonding the first handle from the integrated circuit substrate, bonding a second handle to a second side of the integrated circuit substrate, attaching at least one electrical contact to the second side of the integrated circuit substrate to couple one electrical element in an integrated circuit, separating individual dice from the thinned integrate circuit substrate and de-bonding the second handle only after mounting the separated die to a substrate.

In yet another embodiment, a non-transient computer readable medium for forming a thinned integrated circuit assembly can include computer code for forming a trench around at least one integrated circuit area included on an integrated circuit substrate, computer code for bonding a handle to the integrated circuit substrate, computer code for locating registration features of the integrated circuit area and forming contacts related to the located features, computer code for separating at least one die from the integrated circuit substrate, computer code for mounting the die to a printed circuit board and computer code for de-bonding the handle from the mounted die.

In another embodiment, a non-transient computer readable medium for forming a thinned integrated circuit assembly can include computer code for bonding a first handle to a first side of an integrated circuit substrate, computer code for thinning a portion of the integrated circuit substrate, computer code for de-bonding the first handle, computer code for bonding a second handle to the second side of the integrated circuit substrate, computer code for separating dice from the integrated circuit substrate and computer code for attaching the separated dice to a supporting substrate.

Other aspects and advantages of the invention will become apparent from the following detailed description taken in conjunction with the accompanying drawings which illustrate, by way of example, the principles of the described embodiments.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by one skilled in the art without departing from the spirit and scope of the described embodiments.

FIG. 1 shows a diagram of a wafer.

FIG. 2 is a flow chart 200 summarizing method steps for forming thinned silicon integrated circuits.

FIGS. 3A-3J show simplified views of possible cross sections of wafer 100 while being processed to form thinned silicon integrated circuits.

FIG. 4 is a flow chart of method steps for forming a thinned integrated circuit.

FIG. 5 is a block diagram of an electronic device suitable for controlling some of the processes in the described embodiment.

FIGS. 6A-6C show simplified views of another embodiment of a thinned integrated circuit.

FIGS. 7A and 7B are a flow chart of another embodiment of method steps for forming a thinned integrated circuit.

### DETAILED DESCRIPTION OF SELECTED EMBODIMENTS

Representative applications of methods and apparatus according to the present application are described in this section. These examples are being provided solely to add context and aid in the understanding of the described embodiments. It will thus be apparent to one skilled in the art that the described embodiments may be practiced without some or all of these specific details. In other instances, well known process steps have not been described in detail in order to avoid unnecessarily obscuring the described embodiments. Other applications are possible, such that the following examples should not be taken as limiting.

In the following detailed description, references are made to the accompanying drawings, which form a part of the description and in which are shown, by way of illustration, specific embodiments in accordance with the described embodiments. Although these embodiments are described in sufficient detail to enable one skilled in the art to practice the described embodiments, it is understood that these examples are not limiting; such that other embodiments may be used, and changes may be made without departing from the spirit and scope of the described embodiments.

Product demands for thinned integrated circuits are steadily increasing. Unfortunately, restrictive form factors are pushing more and more design constraints into thinned integrated device requirements, often causing the thinned circuits to have reliability issues and yield problems especially when the circuits are singulated (separated) from one another. More robust thinned integrated circuits are desired.

One method for producing thinned silicon integrated circuits bonds a silicon (or other feasible substrate) wafer to a “handle”. In some embodiments, the silicon wafer can have undergone most of the processing and metallization steps and can be ready for the attachment of bond wires or other similar packaging steps. The handle can be a temporary stabilizing element that can assist in increasing structural integrity of the silicon wafer. In one embodiment, the handle can be approximately the same size of the silicon wafer and substantially cover the silicon wafer.

After the handle is bonded to a partially processed or fully processed silicon wafer, the wafer can undergo further processing for thinning and, in some cases, the attachment of conductors to the die. The dice on the wafers can then be singulated while the handle is still attached. The attached handle can continue to provide strength to the thinned silicon during and after singulation. Finally, the singulated dice can be mounted on a supporting or electrically interconnecting substrate such as a printed circuit board (PCB) and as a final step, the handle can be removed. The handle can help assure planarity of the thinned silicon when the die is mounted (soldered) to the PCB.

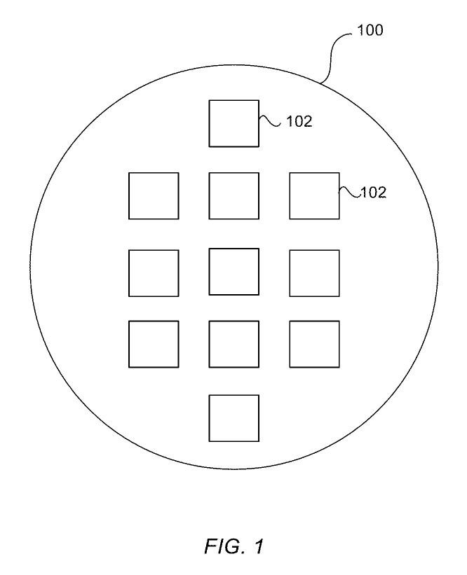

FIG. 1 is a diagram of a wafer 100. The wafer 100 can be a substrate for the formation of integrated circuits. The wafer 100 can be formed from silicon, gallium arsenide, or any other suitable substrate for integrated circuits. Wafer 100 can be manufactured in many sizes. A common size can be eight inches in diameter. Other wafer sizes can be smaller, such as 4 inches, or larger such as twelve inches or more. Integrated circuits can be formed and grouped into elements that will be separated from the wafer 100 to form dice. The integrated circuit groups 102 (that can later be formed into dice) are shown on wafer 100 for reference.

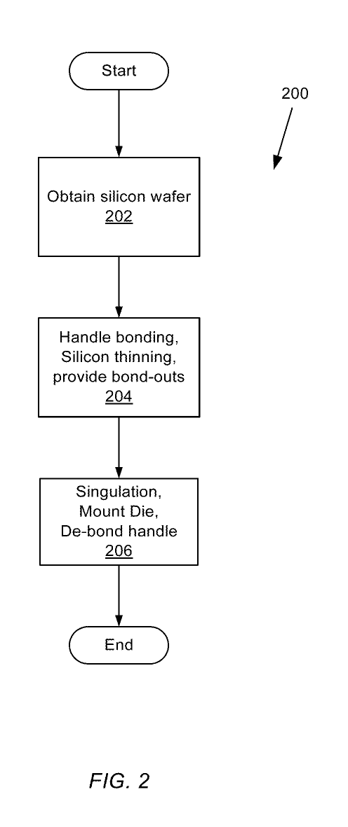

FIG. 2 is a flow chart summarizing method steps for forming thinned silicon integrated circuits. Although the steps and processes described herein reference silicon as the thinned substrate, any other technically feasible substrate can be used. In step 202, a silicon wafer is obtained. In one embodiment, the wafer 100 can have circuits, transistors, sensors, gates etc. formed thereon. In step 204, a handle can be bonded to the wafer 100, the wafer 100 can be thinned and final bond out connections can be added. In step 206, the dice can be singulated, the die mounted and the handle de-bonded. The bonded handle can add strength to the wafer 100 while the wafer 100 is being thinned. Furthermore, leaving the handle bonded onto the die can allow the handle to continue to add strength and stability while the die is handled and ultimately mounted.

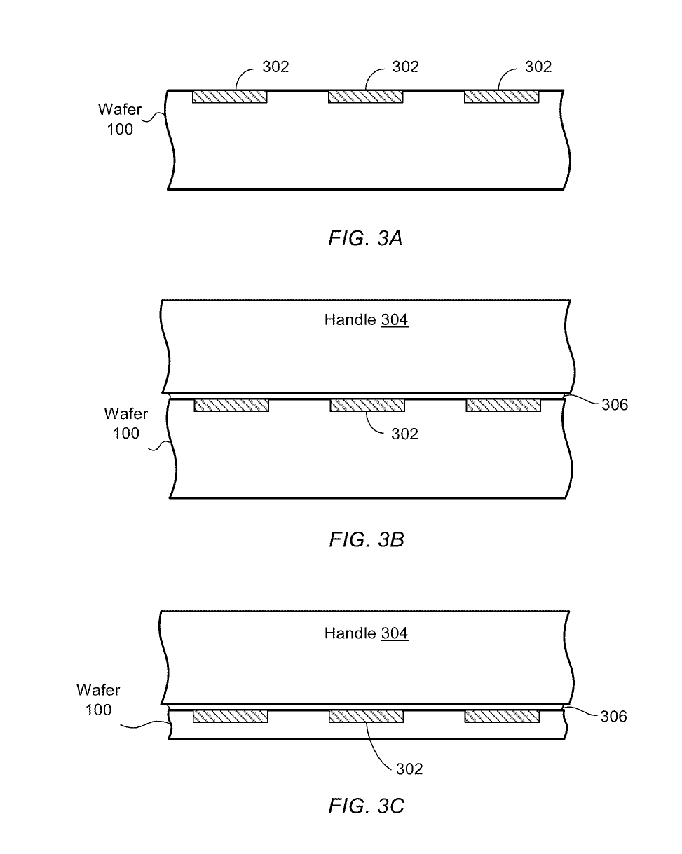

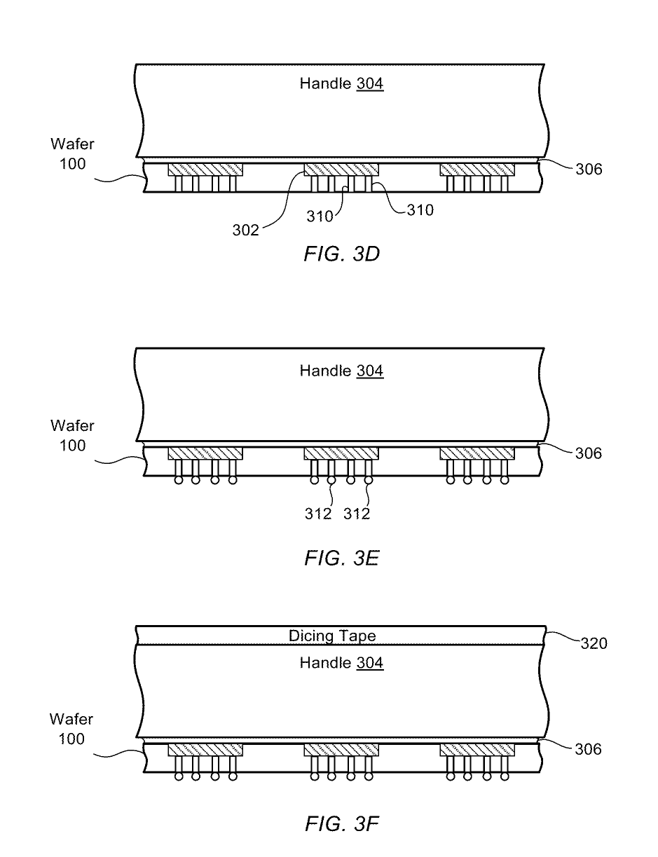

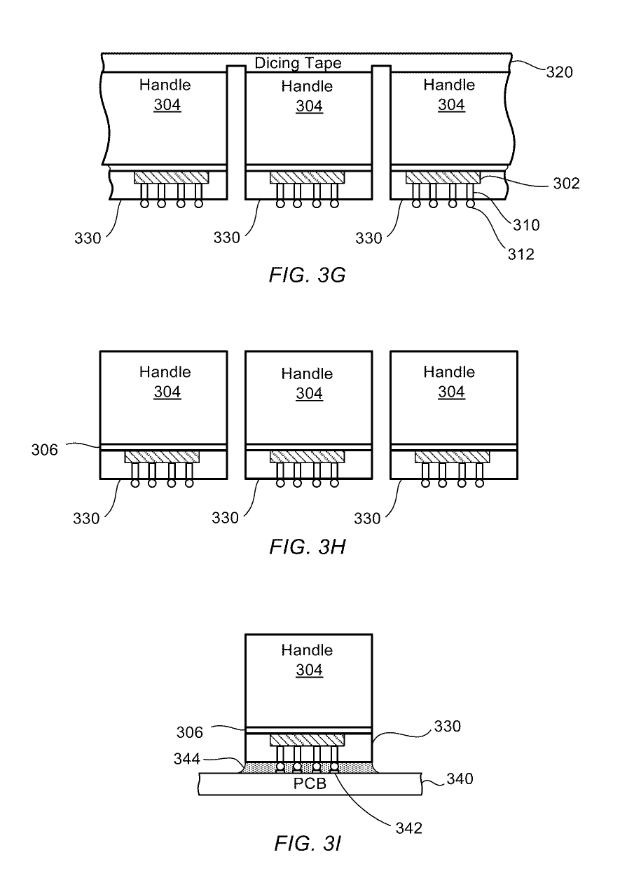

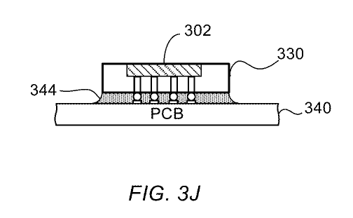

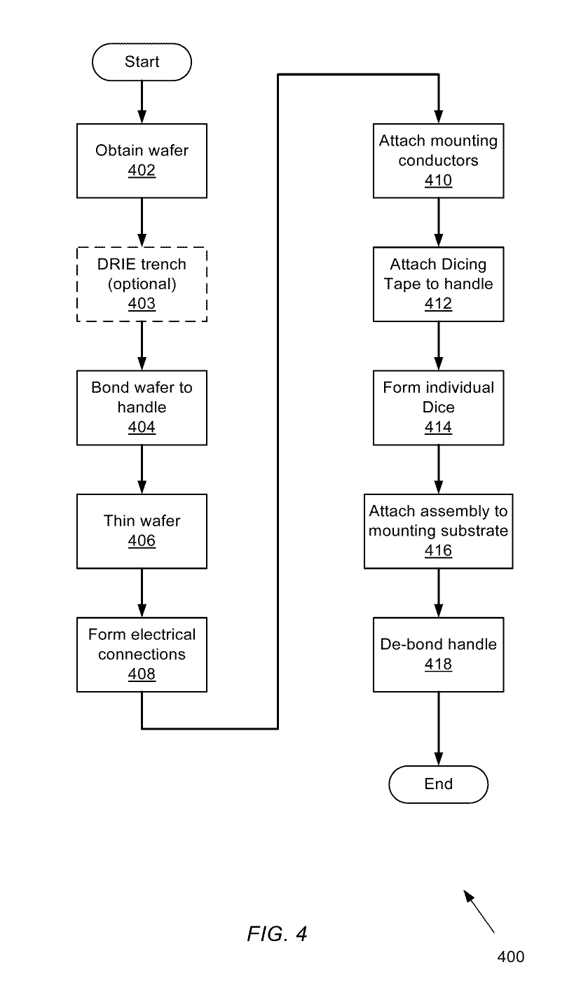

FIGS. 3A-3J show simplified views of possible cross sections of wafer 100 while being processed to form thinned silicon integrated circuits. Generally speaking, steps 202 and 204 are described in FIGS. 3A-3F while step 206 is described in FIGS. 3G-3J.

FIG. 3A shows a cross section of wafer 100. Wafer 100 can be silicon, gallium arsenide, germanium, indium gallium arsenide or any other technically feasible substrate for integrated circuits. Integrated circuits can be formed in circuit areas 302. In one embodiment, integrated circuits in circuit areas 302 can be relatively complete and ready for bond out steps. In other embodiments, integrated circuits in circuit areas 302 can be partially formed and can be fully formed in later steps.

FIG. 3B shows a handle 304 bonded to wafer 100. In one embodiment the handle 304 can be bonded to a side of the wafer 100 that includes circuit areas 302. The handle can be composed of silicon, gallium arsenide, borosilicate glass, alumina or other suitable material. In one embodiment, the coefficient of thermal expansion of the handle can closely match the coefficient of thermal expansion of the wafer 100. In another embodiment, the coefficient of thermal expansion of the handle can be within a predetermined amount of the coefficient of thermal expansion of the wafer 100. The handle 304 can be bonded to the wafer 100 with an adhesive 306. Any suitable adhesive can be used. Adhesive 306 should not deteriorate within typical wafer 100 processing and handling environmental conditions. In one embodiment, an ultra violet (UV) releasable adhesive can be used, particularly when the handle 304 allows the transmission of UV light. In another embodiment, the adhesive 306 can be thermally cured. Handle 304 thickness can vary with wafer 100 diameters. In one embodiment, a 700 micron thick handle 304 can be used with an eight inch wafer 100. In other embodiments, smaller wafer 100 sizes can use thinner handle 304 thicknesses. Alternatively, larger wafer 100 diameters can use thicker handle 304 sizes. Although not shown here, the wafer 100 can be partially trenched between integrated circuit areas 302. The trenching can relieve some stresses that can occur in the wafer, especially when the wafer 100 is subjected to further processing. In one embodiment, the partial trenching can be performed by deep reactive ion etching. This is described in greater detail in FIG. 4.

FIG. 3C shows wafer 100 after thinning. In one embodiment, the wafer 100 can be thinned to a thickness of 100 microns. In another embodiment, the thickness of the wafer can be less than 100 microns. Handle 304 and adhesive 306 can provide additional strength and stability to wafer 100 during the thinning process. In one embodiment, wafer 100 can be thinned by grinding. FIG. 3D shows vias 310 added to the wafer 100. In one embodiment, vias 310 can be formed though the wafer 100 and can couple to elements associated with circuits within circuit area 302. In one embodiment, vias 310 can be laser vias. Vias 310 can also couple to a redistribution layer (RDL, not shown) associated with circuit area 302. Although vias 310 are shown here as coupling to circuit areas 302 through a bottom side, other coupling areas can be used. In one embodiment, location of the vias 310 can be determined in conjunction with visible features contained in circuit areas 302. Such visible features can be visible through handle 304, especially when handle 304 is optically transmissive, such as when handle 304 is composed of borosilicate glass. In other embodiments, certain alignment information regarding circuits within circuit areas 302 can be determined by transferring alignment information from one side of the wafer 100 (i.e., the side including circuit area 302) to the opposing side of wafer 100. In yet another embodiment, vias 310 can be added to wafer 100 prior to thinning. For example, vias 310 can be added after handle 304 is attached to wafer 100, but prior to thinning illustrated in FIG. 3C.

FIG. 3E shows mounting balls 312 attached to wafer 100. In one embodiment, mounting balls 312 can be solid or hollow metallic or semi-metallic spheres suitable to mount and support the wafer 100 to a substrate and also couple electrical signals to and from electrical circuits in electrical areas 302 through vias 310. Handle 304 and adhesive 306 remain attached to wafer 100. FIG. 3F shows dicing tape 320 attached to handle 304. Dicing tape can be a thin, polymer-based tape that is often used in the manufacture of integrated circuits, particularly when individual dice are singulated from a wafer. In other embodiments, other similar adhesive backed carriers can be used. In FIG. 3G, individual dice 330 can be singulated from wafer 100. In one embodiment, dice 330 can be separated by sawing. For example, dice 330 can be separated by sawing through wafer 100 and handle 304 together, in other words, sawing through the combination of the handle 304 attached to the wafer 100. In another embodiment, dice 330 can be at least partially separated using deep reactive ion etching (DRIE). In one embodiment a combination of sawing and DRIE can be used. Note that handle 304 and adhesive 306 are still bonded to the dice 330, thus continuing to provide strength and support for thinned wafer 100. Each die 330 can be a discrete unit including circuit area 302, vias 310 and mounting balls 312. FIG. 3H shows dice 330 with dicing tape 320 removed.

FIG. 3I shows die 330 mounted to a suitable substrate such as a PCB 340. Mounting balls 312 can be aligned with pads 342 on PCB 340 allowing die 330 to be attached to PCB 340. In one embodiment, the die 330 can be soldered to PCB 340 with lead-free solder. Note that handle 304 and adhesive 306 are still attached to die 330 and can continue to provide additional strength and support to the die 330 assembly, even during the mounting process. The addition of handle 304 can help increase planarity of die 330 and reduce the chances of failure after the mounting process. FIG. 3I also shows underfill 344 disposed between die 330 and PCB 340. Underfill 344 can be applied before or after mounting die 330 to PCB 340. Thus, handle 304 and adhesive 306 can still be attached during underfill 344 application. After mounting, the handle 304 and adhesive 306 can be de-bonded (removed) as is shown in FIG. 3J. FIG. 3J shows die 330, mounted to PCB 340 with underfill 344 disposed between die 330 and PCB 340. In one embodiment, the de-bonding can be performed with a thermal, UV or chemical release of adhesive 306 from handle 304 and wafer 100.

FIG. 4 is a flow chart 400 of method steps for forming a thinned integrated circuit in accordance with one embodiment described in the specification. Persons skilled in the art will understand that any system configured to perform the method steps in any order is within the scope of this description. The method can begin in step 402 when wafer 100 is obtained. Wafer 100 can include integrated circuits disposed in circuit areas 302.

Step 403 can be an optional DRIE step to outline dice 330 on the wafer 100. The outlines provided by the DRIE operation can form cuts and/or trenches that serve to isolate areas on the wafer 100, but not completely separate integrated circuit areas 302 from the wafer 100 By forming cuts or trenches with DRIE prior to thinning the wafer 100, some stresses that the dice 330 may be subjected to because of later thinning operations, may be reduced. For example, the DRIE may define rounded corners instead of the sharp 90 degree corners typically used when dice are sawn from a wafer.

In step 404, handle 304 can be bonded to wafer 100. In one embodiment, handle 304 can be bonded to wafer 100 using adhesive 306. Handle 304 can comprise any suitable material, particularly material capable of withstanding the environmental conditions related to wafer 100 processing and preferably with a coefficient of thermal expansion similar to the coefficient of thermal expansion of the wafer 100. In one embodiment, handle 304 can allow at least some light through to wafer 100, or, alternatively, handle 304 can be opaque. In one embodiment, adhesive 306 can be UV releasable; in another embodiment, adhesive 306 can be thermally curable.

In step 406, the wafer 100 can be thinned. In one embodiment, the wafer 100 can be thinned to about 100 microns. Thinning can be accomplished by grinding, for example. In step 408, electrical connections to electrical components included on wafer 100 can be formed. For example, electrical connections can be used to couple electrical signals to and from electrical components included in circuit area 302. In one embodiment, electrical connections can be formed with laser vias. In step 410, mounting conductors can be added to the thinned integrated circuit. In one embodiment, metallic or semi-metallic balls can be coupled to the electrical connections formed in step 408.

In step 412, dicing tape 320 can be applied to wafer 100. In step 414 the dice 330 can be singulated from the wafer 100. In one embodiment, the dice 330 can be sawn to separate them from one another. In another embodiment, dice 330 can be partially or completely singulated with DRIE. Note that at this time, handle 304 and adhesive 306 are still attached to wafer 100, even as individual dice 330 are separated. In step 416, die 330 can be mounted to a substrate such as a PCB 340. In step 418, the handle 304 and adhesive 306 can be removed from the die 330. By maintaining the attachment of the handle 304 to the die 330 until after the mounting process, the strength of the assembly including die 330 and handle 304 can be greater than the strength of the die 330 alone.

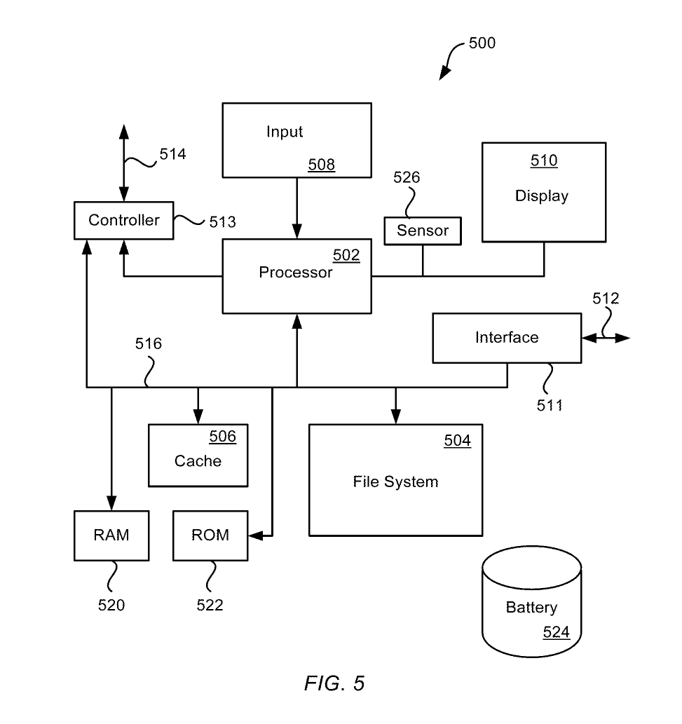

FIG. 5 is a block diagram of an electronic device suitable for controlling some of the processes in the described embodiment, such as processes related to forming a thinned integrated circuit. Electronic device 500 can illustrate exemplary circuitry of a representative computing device. Electronic device 500 can include a processor 502 that pertains to a microprocessor or controller for controlling the overall operation of electronic device 500. Electronic device 500 can include instruction data pertaining to manufacturing instructions in a file system 504 and a cache 506. File system 504 can be a storage disk or a plurality of disks. In some embodiments, file system 504 can be flash memory, semiconductor (solid state) memory or the like. The file system 504 can typically provide high capacity storage capability for the electronic device 500. However, since the access time to the file system 504 can be relatively slow (especially if file system 504 includes a mechanical disk drive), the electronic device 500 can also include cache 506. The cache 506 can include, for example, Random-Access Memory (RAM) provided by semiconductor memory. The relative access time to the cache 506 can substantially shorter than for the file system 504. However, cache 506 may not have the large storage capacity of file system 504. Further, file system 504, when active, can consume more power than cache 506. Power consumption often can be a concern when the electronic device 500 is a portable device that is powered by battery 524. The electronic device 500 can also include a RAM 520 and a Read-Only Memory (ROM) 522. The ROM 522 can store programs, utilities or processes to be executed in a non-volatile manner. The RAM 520 can provide volatile data storage, such as for cache 506

Electronic device 500 can also include user input device 508 that allows a user of the electronic device 500 to interact with the electronic device 500. For example, user input device 508 can take a variety of forms, such as a button, keypad, dial, touch screen, audio input interface, visual/image capture input interface, input in the form of sensor data, etc. Still further, electronic device 500 can include a display 510 (screen display) that can be controlled by processor 502 to display information to the user. Data bus 516 can facilitate data transfer between at least file system 504, cache 506, processor 502, and controller 513. Controller 513 can be used to interface with and control different manufacturing equipment through equipment control bus 514. For example, control bus 514 can be used to control a dicing saw, a deep reactive ion etching machine, a laser via forming machine other such equipment. For example, processor 502, upon a certain manufacturing event occurring, can supply instructions to control manufacturing equipment through controller 513 and control bus 514. Such instructions can be stored in file system 504, RAM 520, ROM 522 or cache 506.

Electronic device 500 can also include a network/bus interface 511 that couples to data link 512. Data link 512 can allow electronic device 500 to couple to a host computer or to accessory devices. The data link 512 can be provided over a wired connection or a wireless connection. In the case of a wireless connection, network/bus interface 511 can include a wireless transceiver. Sensor 526 can take the form of circuitry for detecting any number of stimuli. For example, sensor 526 can include any number of sensors for monitoring a manufacturing operation such as, for example, a Hall Effect sensor responsive to external magnetic field, an audio sensor, a light sensor such as a photometer, computer vision sensor to detect clarity, a temperature sensor to monitor a molding process and so on.

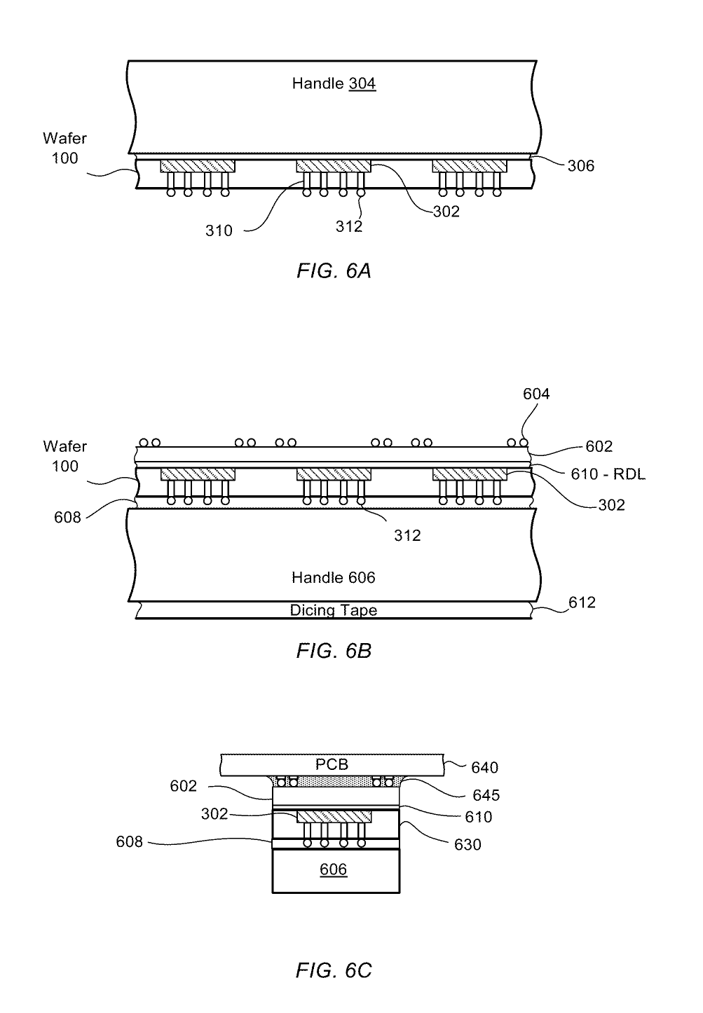

FIGS. 6A-6C show another embodiment of a thinned integrated circuit. In this embodiment, a second handle can be applied, allowing one or more elements to be applied to opposing sides of the wafer 100. FIG. 6A shows wafer 100, thinned and with vias 310 and mounting balls 312. FIG. 6A can be relatively similar to FIG. 3E described earlier. As shown in FIG. 6A, handle 304 can be attached with adhesive 306 to wafer 100.

Handle 304 and adhesive 306 can be removed as described in conjunction with FIG. 3J. In this example, the wafer has not yet been singulated, although handle 304 and adhesive 306 have been removed. Instead a second adhesive layer 608 can be used to bond a second handle 606 to wafer 100 as shown in FIG. 6B. In one embodiment, second adhesive layer 608 and second handle 606 can be similar to handle 304 and adhesive 306 described earlier in conjunction with FIG. 3B. For example, handle 606 can be borosilicate glass and adhesive 608 can be a UV releasable adhesive. A redistribution layer 610 can be formed over circuit area 302. In some embodiments an additional layer 602 can be placed over redistribution layer 610. Together or separately, redistribution layer 610 and additional layer 602 can route electrical connections between circuit area 302 and mounting balls 604. In one embodiment, mounting balls can be similar to mounting balls 312 described above. The use of the second handle 606 advantageously allows placing mounting balls 312 and 604 on two opposing sides (e.g, top and bottom) of circuit area 302 while adding strength and maintaining planarity of wafer 100. The mounting balls 312 and 604 can enable multi-level assemblies to be realized. Singulation of the dice 630 can occur after the mounting balls 604 are added. In some embodiments, dice 630 can be formed with the use of dicing tape 612 and the combination of wafer 100 and second handle 606 can be singulated together.

FIG. 6A is merely illustrative of a possible starting point for the application of second handle 606. In other embodiments, other starting points can be used such as FIG. 3C, FIG. 3D or any other technically feasible starting point.

FIG. 6C shows singulated die 330 mounted to a PCB 640. As before in FIG. 3A-3J, singulated die 330 can remain bonded to second handle 606 as die 330 is mounted on PCB 640. The second handle 606 and second adhesive layer 608 can continue to provide strength and stability to die 330 while being handled and mounted to the PCB 640. FIG. 6C also shows underfill 645 that can be disposed between PCB 640 and die 330. After die 330 is mounted, second handle can be de-bonded and removed from die 330.

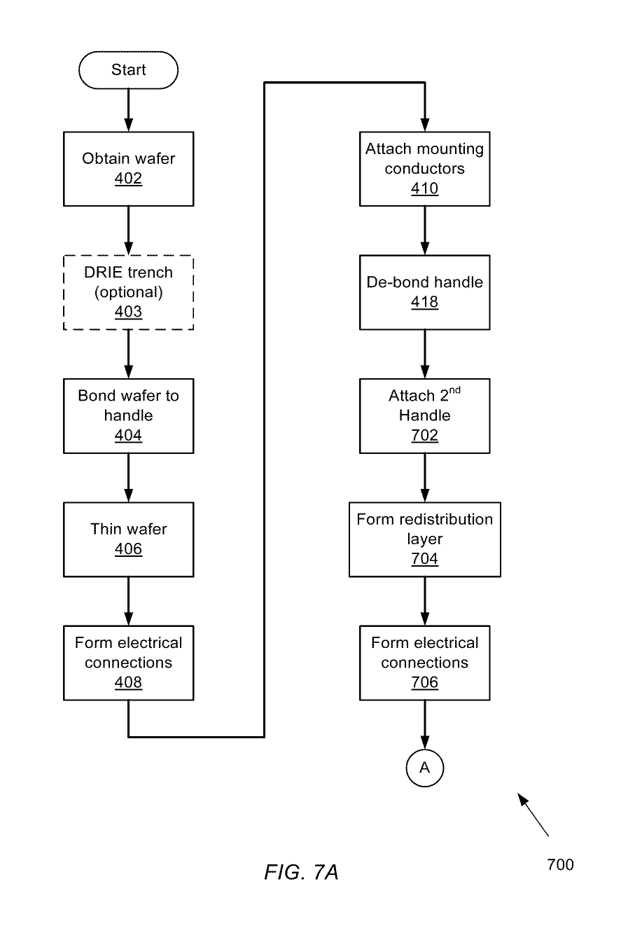

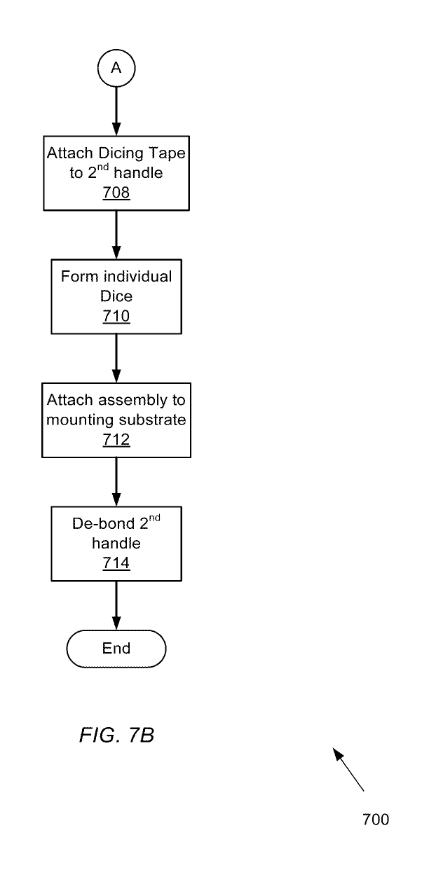

FIGS. 7A and 7B are a flow chart of another embodiment of method steps 700 for forming a thinned integrated circuit in accordance with one embodiment described in the specification. There can be several steps in common with the method described in FIG. 4. Thus steps with the same element numbers as those found in FIG. 4 can be substantially similar.

The method can begin in step 402 when wafer 100 is obtained. Step 403 can be an optional DRIE step to outline dice 330 on the wafer. By forming partial cuts or trenches with DRIE prior to thinning the wafer 100, some stresses that the dice 330 may be subjected to because of later thinning operations, may be reduced. In step 404, a first handle 304 can be bonded to a first side of wafer 100. In one embodiment, the first side can be a side of wafer 100 that can be nearest to circuit area 302. In yet another embodiment, first handle 304 can be bonded to wafer 100 using adhesive 306. In step 406, the wafer 100 can be thinned. In step 408, electrical connections to electrical components included on wafer 100 can be formed. For example, electrical connections can be used to couple electrical signals to and from electrical components included in circuit area 302. In one embodiment, electrical connections can be formed with laser vias. In step 410, mounting conductors can be added to the thinned integrated circuit. In one embodiment, metallic or semi-metallic balls can be coupled to the electrical connections formed in step 408.

Now the method of FIGS. 7A and 7B can deviate from the method described in FIG. 4. Next in step 414, the first handle is de-bonded from the wafer 100. Note that in the method description in FIG. 4, the handle 304 is removed after die 330 is mounted. The methods described for de-bonding the first handle can be substantially similar to the methods described for de-bonding the handle in step 414 in FIG. 4. Next, in step 702, a second handle 606 can be attached to a second side of wafer 100. In one embodiment, the second side of wafer 100 can be in opposition to the first side described in step 404 above. In one embodiment, the second handle 606 can have a similar coefficient of thermal expansion as the wafer 100. Choices for material used for the second handle 606 can be similar to materials used for the first handle 304.

In step 704 a redistribution layer can be formed on the first side of wafer 100. The redistribution layer can be used to route electrical connections into desirable locations on the first side of wafer 100. In step 706, electrical connections can be formed. In one embodiment, the electrical connections can be formed with laser vias. In step 708, dicing tape can be attached to the second handle. In step 710, individual dice 630 can be formed from wafer 100. In step 712, the die 630 can be attached to a substrate. After attachment, in step 714 the second handle can be de-bonded from the wafer.

The various aspects, embodiments, implementations or features of the described embodiments can be used separately or in any combination. Various aspects of the described embodiments can be implemented by software, hardware or a combination of hardware and software. The described embodiments can also be embodied as computer readable code on a computer readable medium for controlling manufacturing operations or as computer readable code on a computer readable medium for controlling a manufacturing line. The computer readable medium is any data storage device that can store data which can thereafter be read by a computer system. Examples of the computer readable medium include read-only memory, random-access memory, CD-ROMs, HDDs, DVDs, magnetic tape, and optical data storage devices. The computer readable medium can also be distributed over network-coupled computer systems so that the computer readable code is stored and executed in a distributed fashion.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of specific embodiments are presented for purposes of illustration and description. They are not intended to be exhaustive or to limit the described embodiments to the precise forms disclosed. It will be apparent to one of ordinary skill in the art that many modifications and variations are possible in view of the above teachings.

1. A method for forming a thinned circuit assembly, the method comprising:
bonding a handle to a first side of an integrated circuit substrate, the integrated substrate including integrated circuit areas disposed on a first side of the integrated circuit substrate, wherein the handle substantially covers the integrated circuit substrate;
forming at least one electrical contact through a second side of the integrated circuit substrate, the second side opposing the first side;
thinning the integrated circuit substrate;
separating individual dice from the thinned integrated circuit substrate; and
de-bonding the handle from the individual dice only after affixing the separated dice to a supporting substrate.

2. The method of claim 1, further comprising forming at least one trench between integrated circuit areas disposed on the first side, partially separating integrated circuit dice, the dice including at least one integrated circuit.

3. The method of claim 1, wherein the handle comprises a coefficient of thermal expansion within a predetermined amount of the coefficient of thermal expansion of the integrated circuit substrate.

4. The method of claim 1, wherein the handle comprises borosilicate glass.

5. The method of claim 3, wherein the bonding further comprises applying an adhesive arranged to release in the presence of ultra violet light.

6. The method of claim 1, wherein at least one of the electrical connections is a laser via.

7. A method for forming a thinned circuit assembly, the method comprising:
bonding a first handle to a first side of an integrated circuit substrate;
thinning the integrated circuit substrate;
de-bonding the first handle from the integrated circuit substrate;
bonding a second handle to a second side of the integrated circuit substrate only after de-bonding the first handle, wherein the second handle substantially covers the integrated circuit substrate, and wherein the second side is in opposition to the first side;
attaching at least one electrical contact to the second side of the integrated circuit substrate, wherein the at least one electrical contact is coupled to one electrical element in at least one integrated circuit area disposed on the first side of the integrated circuit substrate;
separating individual dice from the thinned integrated circuit substrate; and
de-bonding the second handle from the individual dice only after affixing the separated die to a supporting substrate.

8. The method of claim 7 further comprising attaching at least one electrical contact to the integrated circuit substrate by locating features in the at least one integrated circuit area visible through the first handle.

9. The method of claim 8, wherein the first and second handles comprise coefficients of thermal expansion similar to the integrated circuit substrate.

10. The method of claim 8, wherein the affixing further comprises disposing underfill between the supporting substrate and the individual dice.

11. The method of claim 8, wherein the second handle is bonded to the integrated circuit substrate using an ultra-violet releasable adhesive.

12. The method of claim 11, wherein the second handle comprises borosilicate glass.

13. The method of claim 8, wherein the second handle is bonded with a thermally curable adhesive.

14. Non-transient computer readable medium for storing computer code executable by a processor in a computer system for forming a thinned integrated circuit assembly, the computer readable medium comprising:
computer code for forming a trench around at least one integrated circuit area included on an integrated circuit substrate, wherein the trench does not completely separate individual integrated circuit areas into singulated dice;
computer code for bonding a handle to the integrated circuit substrate;
computer code for locating registration features of the integrated circuit area and forming electrical contacts in accordance with the located registration features;
computer code for separating at least one die from the integrated circuit substrate;
computer code for mounting the die to a printed circuit board; and
computer code for de-bonding the handle from the mounted die.

15. The computer readable medium of claim 14, wherein the handle comprises a coefficient of thermal expansion within a predetermined amount of the coefficient of thermal expansion of the integrated circuit substrate.

16. The computer readable medium of claim 14, wherein the handle comprises borosilicate glass.

17. The computer readable medium of claim 16 wherein locating registration features further comprises computer code for using features in integrated circuit areas visible though the handle to locate the electrical contacts.

18. The computer readable medium of claim 17, further comprising computer code for thinning the integrated circuit substrate.

19. Non-transient computer readable medium for storing computer code executable by a processor in a computer system for forming a thinned integrated circuit assembly, the computer readable medium comprising:
computer code for bonding a first handle to a first side of an integrated circuit substrate;
computer code for thinning a portion of the integrated circuit substrate;
computer code for de-bonding the first handle from the integrated circuit substrate;
computer code for bonding a second handle to a second side of the integrated circuit substrate, the second side in opposition to the first side only after the first handle is de-bonded;
computer code for separating dice from the integrated circuit substrate; and
computer code for attaching the separated dice to a supporting substrate.

20. The computer readable medium of claim 19, further including computer code for forming a redistribution layer over at least a portion of the integrated circuit substrate.

21. The computer readable medium of claim 20, further including computer code for de-bonding the second handle.
